(19) United States
(12) Patent Application Publication
(10) Pub. No.: US 2026/0004031 A1
(43) Pub. Date: Jan. 1, 2026

(54) WATER DEMAND FORECASTING METHOD AND SYSTEM, DEVICE, AND MEDIUM

(71) Applicants: GUANGDONG RESEARCH INSTITUTE OF WATER RESOURCES AND HYDROPOWER, Guangzhou (CN); SUN YAT-SEN UNIVERSITY, Guangzhou (CN)

(72) Inventors: Zejun LI, Guangzhou (CN); Jingwen ZHANG, Guangzhou (CN); Chao TAN, Guangzhou (CN); Bikui ZHAO, Guangzhou (CN); Bensheng HUANG, Guangzhou (CN); Danni JIA, Guangzhou (CN)

(73) Assignees: GUANGDONG RESEARCH INSTITUTE OF WATER RESOURCES AND HYDROPOWER, Guangzhou (CN); SUN YAT-SEN UNIVERSITY, Guangzhou (CN)

(21) Appl. No.: 19/238,227

(22) Filed: Jun. 13, 2025

(30) Foreign Application Priority Data
Jun. 26, 2024 (CN) 2024108343766

(51) Int. Cl. G06F 30/28; G06Q 50/06

(52) U.S. Cl. CPC G06F 30/28; G06Q 50/06

(57) ABSTRACT

A water demand forecasting method includes: preprocessing first raw water consumption data to obtain first historical water consumption data and preprocessing second raw water consumption data to obtain second historical water consumption data; constructing a network structure model based on the first historical water consumption data and the second historical water consumption data, and acquiring a spatial water demand correlation strength output by the network structure model; inputting the first historical water consumption data into a temporal memory model for forecasting a water demand of the first water consumption region based on temporal dependencies in the first historical water consumption data, resulting in a first temporal water demand forecast result; and applying spatial adjustment, based on the spatial water demand correlation strength and the second historical water consumption data, to the first temporal water demand forecast result, to obtain a target water demand result.

### CROSS-REFERENCE TO RELATED APPLICATION

This application is based on and claims the benefit of priority from Chinese Patent Application No. 202410834376.6, filed on 26 Jun. 2024, the entirety of which is incorporated by reference herein.

### TECHNICAL FIELD

The present disclosure relates to the technical field of water conservancy, and in particular, to a water demand forecasting method and system, a device, and a medium.

### BACKGROUND

Rational water demand forecasting serves as a fundamental basis for the planning, design and operational management of water conservancy projects. During the planning phase, accurate forecasts of water demand for a target planning year directly influence decisions regarding project scale, spatial layout and investment priorities. In the operational phase, water demand forecasts across various time horizons—ranging from medium- and long-term to short-term and real-time—play a pivotal role in the formulation of scheduling strategies and the optimization of benefit-risk trade-offs.

Conventional water demand forecasting methods generally fall into two categories: the quota analysis method and the trend extrapolation method. The quota analysis method uses sector-specific water use quotas as main parameters, combined with socio-economic development indicators to estimate future water demand, whereas the trend extrapolation method is based on historical water consumption data, using trend extrapolation to forecast future water demand.

However, both conventional methods exhibit notable limitations in terms of objectivity and predictive accuracy. One fundamental drawback is the assumption that water consumption regions behave as isolated systems, thereby neglecting the spatial interdependencies that commonly exist between adjacent areas. In practice, socio-economic development in one region often exerts spillover effects on neighboring regions through industrial linkages, population migration, and shared environmental or cultural characteristics. For example, neighboring regions may exhibit similar water consumption habits and industrial structures due to frequent population exchange, comparable economic activities, and cultural proximity. As a result, water demand in one region is shaped not only by its own historical patterns but also by the dynamics of surrounding areas, reflecting a strong degree of spatial correlation.

Accordingly, there is a clear and urgent need in the art for a water demand forecasting methodology that can simultaneously account for both temporal continuity and spatial correlation across multiple water consumption regions. Such a method should be capable of modeling complex spatiotemporal interactions and producing water demand forecasts that are both more objective and more accurate.

### SUMMARY

The present disclosure aims to solve one of the technical problems existing in the prior art at least to a certain extent.

To this end, an objective of embodiments of the present disclosure is to provide a water demand forecasting method that can effectively improve the objectivity and accuracy of water demand forecasting.

Another objective of the embodiments of the present disclosure is to provide a water demand forecasting system.

In order to achieve the technical objective, the technical scheme used by an embodiment of the present disclosure includes the following aspects.

In accordance with a first aspect of the present disclosure, an embodiment provides a water demand forecasting method, including:
acquiring first raw water consumption data corresponding to a first water consumption region and second raw water consumption data corresponding to a second water consumption region;
preprocessing the first raw water consumption data to obtain first historical water consumption data, and preprocessing the second raw water consumption data to obtain second historical water consumption data;
constructing a network structure model based on the first historical water consumption data and the second historical water consumption data, and acquiring a spatial water demand correlation strength output by the network structure model, where the spatial water demand correlation strength is used to characterize a degree of influence from water demand changes in the second water consumption region on the first water consumption region, and the first water consumption region neighbors the second water consumption region;
inputting the first historical water consumption data into a temporal memory model for forecasting a water demand of the first water consumption region based on temporal dependencies in the first historical water consumption data, resulting in a first temporal water demand forecast result; and
applying spatial adjustment, based on the spatial water demand correlation strength and the second historical water consumption data, to the first temporal water demand forecast result to obtain a target water demand result.

Additionally, the water demand forecasting method according to the above embodiment of the present disclosure may have the following additional technical features.

Further, in an embodiment of the present disclosure, preprocessing target water consumption data to obtain target historical data includes:
filtering the target water consumption data to obtain maximum water consumption data and minimum water consumption data; and
normalizing the target water consumption data based on the maximum water consumption data and the minimum water consumption data to obtain the target historical data,
where the target water consumption data is either the first raw water consumption data or the second raw water consumption data, the target historical data is either the first historical water consumption data or the second historical water consumption data, and the target historical data corresponds to the target water consumption data.

Further, in an embodiment of the present disclosure, the network structure model is constructed by:
acquiring preset orientation rules;
constructing a complete graph of nodes based on the first historical water consumption data and the second historical water consumption data;
performing a pair-wise independence test/update on a pair of nodes in the complete graph of nodes to obtain an undirected graph of nodes; and
performing an orientation update on the undirected graph of nodes according to the orientation rules to obtain the network structure model.

Further, in an embodiment of the present disclosure, performing a pair-wise independence test/update on a pair of nodes in the complete graph of nodes includes:
acquiring a preset significance indicator and a pair of nodes in the complete graph of nodes, as well as a set of nodes corresponding to the pair of nodes;
performing a test of independence on the pair of nodes based on the set of nodes to obtain an independence statistic;
comparing the independence statistic with the significance indicator to obtain a comparison result; and
removing an undirected edge corresponding to the pair of nodes in response to the comparison result indicating that the independence statistic is greater than the significance indicator; or, retaining an undirected edge corresponding to the pair of nodes in response to the comparison result indicating that the independence statistic is less than or equal to the significance indicator.

Further, in an embodiment of the present disclosure, performing a test of independence on the pair of nodes based on the set of nodes to obtain an independence statistic includes:
acquiring a first node and a second node from the pair of nodes;
performing a first conditional probability test on the first node based on the set of nodes to obtain a first node probability, and performing a second conditional probability test on the first node based on the set of nodes and the second node to obtain a second node probability; and
performing a statistical test on the second node probability based on the first node probability to obtain the independence statistic.

Further, in an embodiment of the present disclosure, a conditional probability expression of the third node corresponding to the first historical water consumption data in the network structure model is:

$$P ( {X}_{i} ( t ) \vert P a ( {X}_{i} ) ) = 𝒩 ( {μ}_{i} ( t ) + {\sum }_{j ∈ P a ( {X}_{i} )} {β}_{ij} {X}_{j} ( t ) , {σ}_{i}^{2} )$$

where P(⋅) is a conditional probability distribution in the network structure model; i is an index of the third node; Xᵢ(t) is the third node during the time period t; Pa(Xᵢ) is the set of the parent nodes for the third node Xᵢ; Xⱼ(t) is the j-th parent node in the set Pa(Xᵢ) during the time period t; [symbol] (⋅) is Gaussian distribution; μᵢ(t) is the mean of the third node during the time period t; βᵢⱼ is the weight parameter between the third node and the parent node Xⱼ; and σᵢ² is a variance of the third node.

Further, in an embodiment of the present disclosure, applying spatial adjustment, based on the spatial water demand correlation strength and the second historical water consumption data, to the first temporal water demand forecast result to obtain a target water demand result includes:
acquiring, based on the temporal memory model, a second temporal water demand forecast result corresponding to the second water consumption region;
performing intra-region spatial adjustment on the second temporal water demand forecast result based on the spatial water demand correlation strength and the second historical water consumption data to obtain intra-region correction data; and
performing neighboring-region spatial adjustment on the first temporal water demand forecast result based on the intra-region correction data to obtain the target water demand result.

In accordance with a second aspect of the present disclosure, an embodiment provides a water demand forecasting system, including:
an acquisition module, which is configured to acquire first raw water consumption data corresponding to a first water consumption region and second raw water consumption data corresponding to a second water consumption region;
a processing module, which is configured to preprocess the first raw water consumption data to obtain first historical water consumption data, and preprocess the second raw water consumption data to obtain second historical water consumption data;
a construction module, which is configured to construct a network structure model based on the first historical water consumption data and the second historical water consumption data, and acquire a spatial water demand correlation strength output by the network structure model, where the spatial water demand correlation strength is used to characterize a degree of influence from water demand changes in the second water consumption region on the first water consumption region, and the first water consumption region neighbors the second water consumption region;
a forecasting module, which is configured to input the first historical water consumption data into a temporal memory model for forecasting a water demand of the first water consumption region based on temporal dependencies in the first historical water consumption data, resulting in a first temporal water demand forecast result; and
a correction module, which is configured to apply spatial adjustment, based on the spatial water demand correlation strength and the second historical water consumption data, to the first temporal water demand forecast result to obtain a target water demand result.

In accordance with a third aspect of the present disclosure, an embodiment further provides an electronic device, including:
at least one processor; and
at least one memory for storing at least one program, where
the at least one program, when executed by the at least one processor, causes the at least one processor to implement the method of the first aspect.

In accordance with a fourth aspect of the present disclosure, an embodiment further provides a computer-readable storage medium storing a processor-executable program which, when executed by a processor, causes the processor to implement the method of the first aspect.

Some of the advantages and beneficial effects of the present disclosure will be set forth in the following description, and some will become apparent from the following description, or be learned by practice of the present disclosure.

Embodiments of the present disclosure disclose a water demand forecasting method and system, a device, and a medium. According to the forecasting method, by acquiring first raw water consumption data corresponding to a first water consumption region and second raw water consumption data corresponding to a second water consumption region; preprocessing the first raw water consumption data to obtain first historical water consumption data, and preprocessing the second raw water consumption data to obtain second historical water consumption data; constructing a network structure model based on the first historical water consumption data and the second historical water consumption data, and acquiring a spatial water demand correlation strength output by the network structure model, where the spatial water demand correlation strength is used to characterize a degree of influence from water demand changes in the second water consumption region on the first water consumption region, and the first water consumption region neighbors the second water consumption region; inputting the first historical water consumption data into a temporal memory model for forecasting a water demand of the first water consumption region based on temporal dependencies in the first historical water consumption data, resulting in a first temporal water demand forecast result; and applying spatial adjustment, based on the spatial water demand correlation strength and the second historical water consumption data, to the first temporal water demand forecast result, a target water demand result is obtained. The forecasting method, based on the spatial water demand correlation strength output by the network structure model and the first temporal water demand forecast result output by the temporal memory model, can ensure that the final target water demand result not only focuses on the temporal continuity of water demand data but also considers the spatial correlation between water demand data across different regions, which achieves the spatiotemporal iterative evolution of water demand and provides more objective and accurate water demand forecast results over different time scales.

### BRIEF DESCRIPTION OF DRAWINGS

In order to clearly illustrate the technical schemes in the embodiments of the present disclosure or the prior art, accompanying drawings related to the technical schemes in the embodiments of the present disclosure or the prior art will be briefly introduced below. It should be understood that the accompanying drawings described below are merely for the convenience of clearly expressing some embodiments of the technical schemes of the present disclosure, and for those having ordinary skill in the art, other drawings can be derived from these drawings without any inventive effort.

FIG. 1 is a flowchart of a water demand forecasting method according to an embodiment of the present disclosure;

FIG. 2 is a schematic diagram of a water demand forecasting system according to an embodiment of the present disclosure; and

FIG. 3 is a schematic diagram of an electronic device according to an embodiment of the present disclosure.

### DETAILED DESCRIPTION

Embodiments of the present disclosure will be discussed in detail below. Examples of the embodiments are illustrated in the accompanying drawings, where the same or like reference numerals throughout the figures indicates the same or like elements having the same or like functions. The embodiments described below with reference to the accompanying drawings are exemplary and are intended only to explain the present disclosure instead of being construed as limiting the present disclosure. For the step numbers in the following embodiments, they are set merely for the convenience of explanation and do not impose any restrictions on the order of the steps. The execution order of the steps in the embodiments can be adaptively adjusted according to the understanding of those having ordinary skill in the art.

Unless otherwise defined, all the technical and scientific terms used herein have the same meanings as those commonly understood by those having ordinary skill in the art to which the present disclosure pertains. The terminology used herein is for the purpose of describing embodiments of the present disclosure only and is not intended to limit the present disclosure.

Currently, traditional water demand forecasting methods mainly include two categories: quota analysis method and trend method. The quota analysis method uses water quotas of various industries as main parameters, combined with socio-economic development indicators to forecast water demand, whereas the trend method is based on historical data, using trend extrapolation to forecast future water demand. However, the changes in water demand in a region are not independent. The socio-economic development of one region can affect neighboring regions to varying degrees through spillover effects, and neighboring regions often have similar water consumption habits and industrial structures due to cultural proximity and high personnel mobility. For example, water consumption region A and water consumption region B spatially neighbor each other, and region A bears the overflow of industries and personnel from region B. Therefore, the changes in water demand in region A not only depend on the historical patterns of water consumption but are also influenced by changes in water demand in neighboring regions, meaning that changes in water demand exhibit both temporal continuity and spatial correlation. These two traditional methods often focus solely on temporal continuity while neglecting spatial correlation, resulting in a lower degree of objectivity and accuracy in water demand forecasting.

In view of this, an embodiment of the present disclosure provides a water demand forecasting method. The forecasting method, based on the spatial water demand correlation strength output by the network structure model and the first temporal water demand forecast result output by the temporal memory model, can ensure that the final target water demand result not only focuses on the temporal continuity of water demand data but also considers the spatial correlation between water demand data across different regions, which achieves the spatiotemporal iterative evolution of water demand and provides more objective and accurate water demand forecast results over different time scales.

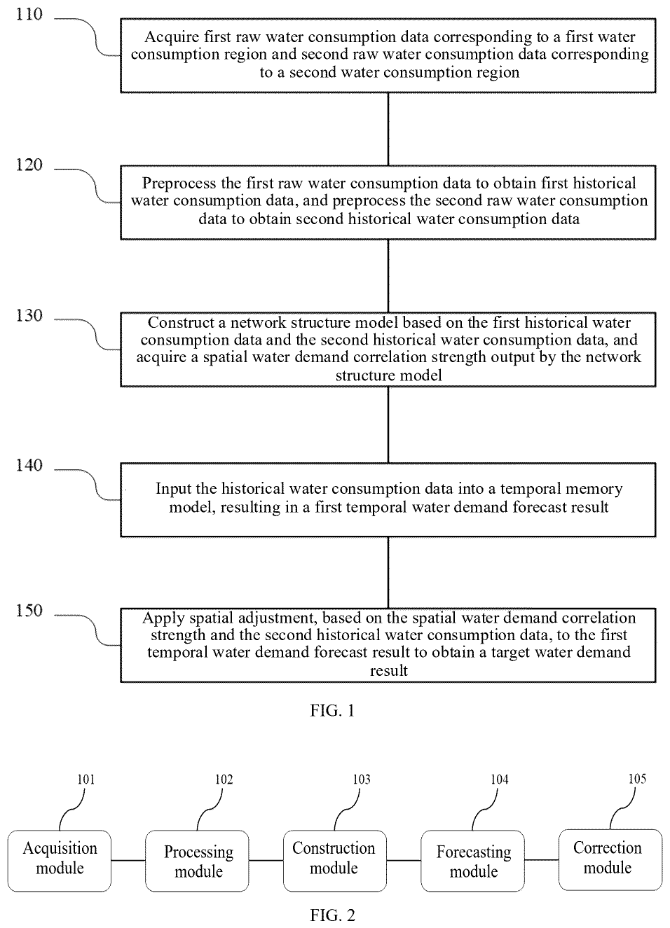

Referring to FIG. 1, in an embodiment of the present disclosure, a water demand forecasting method includes the following steps.

Step 110: acquiring first raw water consumption data corresponding to a first water consumption region and second raw water consumption data corresponding to a second water consumption region.

In an embodiment of the present disclosure, the first water consumption region and the second water consumption region may be specific water consumption regions, where the first water consumption region is the target water consumption region for which water demand forecasting is to be made, and the second water consumption region is a water consumption region neighboring the first water consumption region, where the number of the second water consumption region is greater than or equal to 1. The first raw water consumption data is historical water demand data within the first water consumption region, which may be represented based on a time series, and the second raw water consumption data is similarly structured.

Step 120: preprocessing the first raw water consumption data to obtain first historical water consumption data, and preprocessing the second raw water consumption data to obtain second historical water consumption data.

In some embodiments, preprocessing target water consumption data to obtain target historical data includes:
A1: filtering the target water consumption data to obtain maximum water consumption data and minimum water consumption data; and
A2: normalizing the target water consumption data based on the maximum water consumption data and the minimum water consumption data to obtain the target historical data.

Herein, the target water consumption data is either the first raw water consumption data or the second raw water consumption data, the target historical data is either the first historical water consumption data or the second historical water consumption data, and the target historical data corresponds to the target water consumption data.

In an embodiment of the present disclosure, the target water consumption data may be either the first raw water consumption data or the second raw water consumption data. In an embodiment of the present disclosure, taking the target water consumption data being the first raw water consumption data as an example, the preprocessing may be data normalization of the first raw water consumption data. Specifically, Step A1 may first involve filtering the first raw water consumption data to obtain the maximum and minimum values thereof, thereby selecting the maximum data sample as the maximum water consumption data and the minimum data sample as the minimum water consumption data from the first raw water consumption data. Step A2 may normalize all data samples in the first raw water consumption data based on the Min-Max normalization formula, thus obtaining the first historical water consumption data.

It is to be noted that when the target water consumption data is the second raw water consumption data, the steps are similar to the above content when the target water consumption data is the first raw water consumption data, and can be simply inferred.

For example, the target historical data can be expressed equivalently as:

$${X}_{i} ( t ) = \frac{{X}_{i}^{orig} ( t ) - min ( {X}_{i}^{orig} )}{max ( {X}_{i}^{orig} ) - min ( {X}_{i}^{orig} )}$$

where Xᵢ(t) is target historical data of water consumption region i during time period t;

$${X}_{i}^{orig} ( t )$$

is target water consumption data of water consumption region i during time period t;

$$min ( {X}_{i}^{orig} )$$

is the minimum water consumption data of water consumption region i;

$$max ( {X}_{i}^{orig} )$$

is the maximum water consumption data of water consumption region i; and water consumption region i may be either the first water consumption region or the second water consumption region.

Step 130: constructing a network structure model based on the first historical water consumption data and the second historical water consumption data, and acquiring a spatial water demand correlation strength output by the network structure model, where the spatial water demand correlation strength is used to characterize a degree of influence from water demand changes in the second water consumption region on the first water consumption region, and the first water consumption region neighbors the second water consumption region.

In an embodiment of the present disclosure, the network structure model may be a Bayesian network structure, which is used to characterize the degree of mutual influence of water demand changes between different water consumption regions, and may be constructed using expert experience methods or network structure learning algorithms.

In some embodiments, the network structure model in step 130 is constructed through the following steps:
B1: acquiring preset orientation rules;
B2: constructing a complete graph of nodes based on the first historical water consumption data and the second historical water consumption data.

In an embodiment of the present disclosure, specifically, the network structure model may be constructed based on the Peter-Clark Algorithm (PC algorithm). The preset orientation rules are used to orient the edges in the undirected graph of nodes to generate a directed acyclic network structure model. Step B2 may involve using the first historical water consumption data corresponding to the first water consumption region as the first water consumption node in the complete graph of nodes, and using the second historical water consumption data corresponding to the second water consumption region as the second water consumption node in the complete graph of nodes, with the number of second water consumption node being greater than or equal to 1, thus constructing the complete graph of nodes.

It is understandable that there is an undirected edge between every pair of nodes in the complete graph of nodes. For example, if a certain complete graph of nodes includes four nodes A, B, C, and D, then this complete graph of nodes includes undirected edges A-B, undirected edge A-C, undirected edge A-D, undirected edge B-C, undirected edge B-D, and undirected edge C-D. This example in the application is for illustration purposes only and does not impose any limitations on the application. The actual number of nodes in the complete graph of nodes can be derived from the total number of the first water consumption region and the second water consumption region.

B3: performing a pair-wise independence test/update on a pair of nodes in the complete graph of nodes to obtain an undirected graph of nodes.

Further, the step B3 of performing a pair-wise independence test/update on a pair of nodes in the complete graph of nodes includes the following sub-steps.

B31: acquiring a preset significance indicator and a pair of nodes in the complete graph of nodes, as well as a set of nodes corresponding to the pair of nodes.

In an embodiment of the present disclosure, the significance indicator is used as the significance level threshold associated with the independence statistic, and the pairs of nodes in the complete graph of nodes may be composed of a first water node and a second water node, or may be composed of different second water nodes. It can be understood that this example of the present disclosure uses a specific pair of nodes in the complete graph of nodes; for that pair of nodes, the corresponding set of nodes is used to test whether the two nodes in the pair are independent under that set of nodes.

B32: performing a test of independence on the pair of nodes based on the set of nodes to obtain an independence statistic.

Further, the step B32 of performing a test of independence on the pair of nodes based on the set of nodes to obtain an independence statistic includes:
B321: acquiring a first node and a second node from the pair of nodes;
B322: performing a first conditional probability test on the first node based on the set of nodes to obtain a first node probability, and performing a second conditional probability test on the first node based on the set of nodes and the second node to obtain a second node probability; and
B323: performing a statistical test on the second node probability based on the first node probability to obtain the independence statistic.

In an embodiment of the present disclosure, for a specific pair of nodes, in a complete graph of nodes, which include a first node X and a second node Y, first, the conditional probability of the first node under the set of nodes S can be calculated to obtain a first node probability, which can be represented as P(X,S), and then, under the condition of the occurrence of the second node, a conditional probability of the first node under the set of nodes can be calculated to obtain a second node probability, which can be represented as P(X|Y, S). It can be understood that the statistical test in step B323 may be based on methods such as chi-squared test, Fisher's exact test, G² test, etc., to determine whether the first node and the second node are independent from each other under the set of nodes.

B33: comparing the independence statistic with the significance indicator to obtain a comparison result.

B34: removing an undirected edge corresponding to the pair of nodes in response to the comparison result indicating that the independence statistic is greater than the significance indicator; or, retaining an undirected edge corresponding to the pair of nodes in response to the comparison result indicating that the independence statistic is less than or equal to the significance indicator.

In an embodiment of the present disclosure, step B33 may involve comparing the calculated independence statistic with the significance indicator; if the comparison result indicates that the independence statistic is greater than the preset significance indicator, then the first node and the second node are conditionally independent, and the undirected edge between the first node and the second node is removed; alternatively, if the comparison result indicates that the independence statistic is less than or equal to the preset significance indicator, then the first node and the second node are not conditionally independent, and the undirected edge between the first node and the second node is retained.

It can be understood that the remaining pairs of nodes in the complete graph of nodes are similar to the aforementioned pair of nodes, and the steps B31 to B34 in the embodiment of the present disclosure may be repeated to ensure that all pairs of nodes in the complete graph of nodes complete independence updates, and the complete graph of nodes after independence updates is taken as the undirected graph of nodes.

B4: performing an orientation update on the undirected graph of nodes according to the orientation rules to obtain the network structure model.

In an embodiment of the present disclosure, the orientation rules include undirected edge orientation rules, cycle avoidance rules, and parent node determination rules, where the undirected edge orientation rules specifically state that for a pair of nodes (X, Y), if there is an undirected edge X-Y between the first node X and the second node Y, and there exists a third node Z such that X→Z→Y, then the undirected edge X-Y is updated to a directed edge X→Y; the cycle avoidance rules specifically state that if a certain directed edge would form a cycle, then that directed edge should be abandoned; and the parent node determination rules specifically state that for each first node X, if the condition set formed by the second node Y makes the first node conditionally independent of other nodes, then the second node is designated as the parent node of the first node, meaning the second node is a neighboring node of the first node.

It is understandable that orientation updates can be based on the aforementioned undirected edge orientation rules, cycle avoidance rules, and parent node determination rules, thus converting the undirected graph of nodes into a directed acyclic graph, and using the resulting directed acyclic graph as the network structure model.

In an embodiment of the present disclosure, since the network structure model is constructed based on a Bayesian network structure, the strength of correlation among various nodes in the network structure model may be represented using conditional probabilities. Specifically, for the third node formed by the first historical water consumption data in the network structure model, its expression in terms of conditional probability in the network structure model is as follows:

$$P ( {X}_{i} ( t ) \vert P a ( {X}_{i} ) ) = 𝒩 ( {μ}_{i} ( t ) + {\sum }_{j ∈ P a ( {X}_{i} )} {β}_{\dot{l} j} {X}_{j} ( t ) , {σ}_{i}^{2} )$$

where P(⋅) is a conditional probability distribution in the network structure model; i is an index of the third node; Xᵢ(t) is the third node during the time period t; Pa(Xᵢ) is the set of the parent nodes for the third node Xᵢ; Xⱼ(t) is the j-th parent node in the set Pa(Xᵢ) during the time period t; [symbol] (⋅) is Gaussian distribution; μᵢ(t) is the mean of the third node during the time period t; βᵢⱼ is the weight parameter between the third node and the parent node Xⱼ; and

$${σ}_{i}^{2}$$

is a variance of the third node.

It should be noted that the parent node Xⱼ is the node formed by the second historical water consumption data (i.e., the second water consumption region) in the network structure model. The mean of the third node during time period t may be estimated using the Locally Estimated Scatterplot Smoothing (LOESS) method. Specifically, for the first historical water consumption data, the window width for each time period t may be selected first, and then a regression weight between the regression data points and the neighboring data points adjacent to the regression data points may be calculated based on the window width and the regression data points for time period t. The regression weight may be determined by the distances between the neighboring data points and the regression data points, and the equivalent expression for the regression weight is as follows:

$$ω ( {x}_{ti} , {x}_{t} ) = {( 1 - {( \frac{\vert {x}_{ti} - {x}_{t} \vert}{d} )}^{3} )}^{3}$$

where ω(xₜᵢ, xₜ) is the regression weight between a regression data point and a neighboring data point during time period t; xₜ is the neighboring data point; xₜ is the regression data point; and d is half of the window width.

After determining the regression weight, a weighted least squares method may be used for local low-order polynomial fitting within the window width of each regression data point, thereby obtaining the mean μᵢ(t) of the third node during the time period t.

It is to be noted that the variance of the third node can be simply determined based on the first historical water consumption data and the mean of the third node during the time period t, which will not be elaborated further in the present disclosure. As for the weight parameter between the third node and the parent node (i.e., spatial water demand correlation strength), this weight parameter is also used to characterize the degree of influence from water demand changes in a water consumption region on neighboring water consumption regions, that is, to characterize the degree of influence on the first water consumption region from the water demand changes in the second water consumption region.

For example, the weight parameter of the third node corresponding to each first water consumption region may be determined by obtaining the set of parent nodes that influence the third node, and constructing a regression model based on the mean value of the third node during time period t, the historical water consumption data corresponding to the third node, as well as the set of parent nodes. The equivalent expression for the regression model is as follows:

$${X}_{i} ( t ) = {μ}_{i} ( t ) + {\sum }_{j ∈ P a ( {X}_{i} )} {β}_{ij} {X}_{j} ( t ) + {ϵ}_{i} ( t )$$

where Xᵢ(t) is the third node during a time period t; μᵢ(t) is a mean of the third node during the time period t; Pa(Xᵢ) is a set of the parent nodes for the third node Xᵢ; Xⱼ(t) is the j-th parent node in the set Pa(Xᵢ) during the time period t; and ϵᵢ(t) is an error term.

Step 140: inputting the first historical water consumption data into a temporal memory model for forecasting a water demand of the first water consumption region based on temporal dependencies in the first historical water consumption data, resulting in a first temporal water demand forecast result.

In an embodiment of the present disclosure, the temporal memory model may be a trained Long Short-Term Memory (LSTM) network that predicts the water demand forecast value for the first water consumption region in the future time period t+1, and this water demand forecast value is taken as the first temporal water demand forecast result.

It can be understood that the future time periods in an embodiment of the present disclosure can also be any of the future time periods such as time period t+2, time period t+3, time period t+6, etc. The specific values of the future time periods may be set according to actual conditions, and the examples in the present disclosure are for illustration and do not impose any limitations on the present disclosure.

Step 150: applying spatial adjustment, based on the spatial water demand correlation strength and the second historical water consumption data, to the first temporal water demand forecast result to obtain a target water demand result.

In an embodiment of the present disclosure, the step 150 of applying spatial adjustment, based on the spatial water demand correlation strength and the second historical water consumption data, to the first temporal water demand forecast result to obtain a target water demand result includes:
Step 151: acquiring, based on the temporal memory model, a second temporal water demand forecast result corresponding to the second water consumption region;
Step 152: performing intra-region spatial adjustment on the second temporal water demand forecast result based on the spatial water demand correlation strength and the second historical water consumption data to obtain intra-region correction data; and
Step 153: performing neighboring-region spatial adjustment on the first temporal water demand forecast result based on the intra-region correction data to obtain the target water demand result.

In an embodiment of the present disclosure, for the first water consumption region and its corresponding first historical water consumption data, the first temporal water demand forecast result of the first water consumption region may be corrected based on the spatial water demand correlation strength and the second historical water consumption data corresponding to each second water consumption region, thereby obtaining the final target water demand result for the first water consumption region. This target water demand result can reflect the impact of the actual water consumption demand of several neighboring second water consumption regions on the water consumption demand of the first water consumption region.

For example, step 151 may involve inputting the second historical water consumption data corresponding to each second water consumption region into a temporal memory model for forecasting, resulting in the second temporal water demand forecast result corresponding to each second water consumption region. The intra-region spatial adjustment of step 152 may involve obtaining, based on the spatial water demand correlation strength and the second historical water consumption data, the corresponding spatial adjustment term of the second temporal water demand forecast result, and using this spatial adjustment term as the intra-region correction data, with the quantity of this intra-region correction data being the same as the number of second water consumption regions, where each intra-region correction term can transmit the water demand impact of the corresponding second water consumption region to the first water consumption region. Step 153 may involve a summation operation of the first temporal demand forecast result and all intra-region correction data, thereby correcting the base forecast value from the first temporal water demand forecast result.

For example, in an embodiment of the present disclosure, for a certain spatiotemporal iterative calculation, the equivalent expression for the target water demand result of the first water consumption region in the future time period t+1 is as follows:

$${\tilde{X}}_{i} ( t + 1 ) = {\hat{X}}_{i} ( t + 1 ) + {\sum }_{j ∈ P a ( {X}_{i} )} {β}_{ij} ( {X}_{j} ( t ) - {\hat{X}}_{j} ( t + 1 ) )$$

where \tilde{X}ᵢ(t+1) is the target water demand result for the first water consumption region in the future time period t+1; \hat{X}ᵢ(t+1) is the first temporal water demand forecast result for the first water consumption region in the future time period t+1; Xⱼ(t) is the second historical water consumption data for the j-th second water consumption region during time period t; and \hat{X}ⱼ(t+1) is the second temporal water demand forecast result for the j-th second water consumption region in the future time period t+1.

It should be noted that when completing the spatiotemporal iterative calculation, the target water demand result obtained from the current calculation iteration may be added to the latest first raw water consumption data, thereby completing the update of the first raw water consumption data; and/or, the second temporal water demand forecast result obtained from the current calculation iteration may be added to the latest second raw water consumption data, thereby completing the update of the second raw water consumption data.

For example, the current time period is t, the time period corresponding to the first spatiotemporal iterative calculation is t+1, and the time period corresponding to the second spatiotemporal iterative calculation is t+2. If the number of calculations corresponding to the current spatiotemporal iterative calculation process is the 2nd time, at this point, the target water demand result for the time period t+1 can be added to the first original water consumption data, and/or the second temporal water demand forecast result for the time period t+1 can be added to the second original water consumption data. The specific method of addition can involve denormalizing the target water demand result and adding the denormalized target water demand result to the latest first raw water consumption data. The update of the second raw water consumption data is similar to that of the first raw water consumption data, and can be similarly inferred, and the present disclosure will not elaborate further.

In summary, the embodiments of the present disclosure, based on the spatial water demand correlation strength output by the network structure model and the first temporal water demand forecast result output by the temporal memory model, can ensure that the final target water demand result not only focuses on the temporal continuity of water demand data but also considers the spatial correlation between water demand data across different regions. This can achieve the spatiotemporal iterative evolution of water demand and provide more objective and accurate water demand forecast results over different time scales (medium to long-term, short-term, and real-time, etc.).

The following describes in detail a water demand forecasting system according to an embodiment of the present disclosure with reference to the accompanying drawings.

Referring to FIG. 2, an embodiment of the present disclosure provides a water demand forecasting system, including:
an acquisition module 101, which is configured to acquire first raw water consumption data corresponding to a first water consumption region and second raw water consumption data corresponding to a second water consumption region;
a processing module 102, which is configured to preprocess the first raw water consumption data to obtain first historical water consumption data, and preprocess the second raw water consumption data to obtain second historical water consumption data;
a construction module 103, which is configured to construct a network structure model based on the first historical water consumption data and the second historical water consumption data, and acquire a spatial water demand correlation strength output by the network structure model, where the spatial water demand correlation strength is used to characterize a degree of influence from water demand changes in the second water consumption region on the first water consumption region, and the first water consumption region neighbors the second water consumption region;
a forecasting module 104, which is configured to input the first historical water consumption data into a temporal memory model for forecasting a water demand of the first water consumption region based on temporal dependencies in the first historical water consumption data, resulting in a first temporal water demand forecast result; and
a correction module 105, which is configured to apply spatial adjustment, based on the spatial water demand correlation strength and the second historical water consumption data, to the first temporal water demand forecast result to obtain a target water demand result.

It can be understood that the contents in the above method embodiments are all applicable to this system embodiment, and the specific functions achieved by the embodiment of the system are the same as those of the above-described method embodiments, and the beneficial effects achieved are also the same as those of the above-described method embodiments.

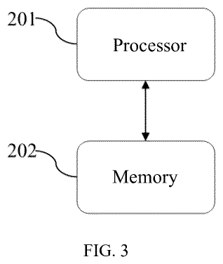

Referring to FIG. 3, an embodiment of the present disclosure further provides an electronic device, including:
at least one processor 201; and
at least one memory 202 for storing at least one program,
where the at least one program, when executed by the at least one processor 201, causes the at least one processor 201 to implement the method embodiments described above.

Similarly, it can be understood that the contents in the above method embodiments are all applicable to this device embodiment. The specific functions achieved by this device embodiment are the same as those of the above-described method embodiments, and the beneficial effects achieved are also the same as those of the above-described method embodiments.

A further embodiment of the present disclosure provides a computer-readable storage medium storing a processor-executable program which, when executed by a processor 201, causes the processor 201 to implement the method embodiments described above.

Similarly, the contents of the method embodiments described above are applicable to this computer-readable storage medium embodiment, and the functions specifically implemented by this computer-readable storage medium embodiment are the same as those of the aforementioned method embodiments, and the beneficial effects achieved are also the same as those achieved by the aforementioned method embodiments.

In some optional embodiments, the functions/operations mentioned in the block diagram may not be performed in the order mentioned in the operation diagram. For example, depending on the functions/operations involved, two blocks shown in succession may in fact be performed substantially simultaneously or the two blocks may sometimes be performed in reverse order. Further, the embodiment presented and described in the flow chart of the present disclosure are provided by way of example in order to provide a more comprehensive understanding of the techniques. The disclosed method is not limited to the operations and logical flows presented herein. Optional embodiments are contemplated in which the order of various operations is changed and in which sub-operations described as part of a larger operation are performed independently.

Furthermore, although the present disclosure has been described in the context of functional modules, it should be understood that, unless otherwise stated, one or more functionalities and/or features may be integrated into a single physical device and/or software module, or one or more functionalities and/or features may be implemented in separate physical devices or software modules. It can also be understood that a detailed discussion of the actual implementation of each module is unnecessary for understanding the present disclosure. More precisely, in light of the attributes, functionalities, and internal relationships of various functional modules disclosed herein, those having ordinary skill in the art will understand the actual implementation of these modules within the routine skills of an engineer. Therefore, those having ordinary skill in the art can implement the aspects of the present disclosure as set forth in the claims using ordinary techniques without excessive experimentation. It can also be understood that the specific concepts disclosed are merely illustrative and are not intended to limit the scope of the present disclosure, which is defined by the full scope of the appended claims and their equivalents.

If the functions are implemented in the form of functional units of software and sold or used as independent products, they can be stored in a computer-readable storage medium. On the basis of such understanding, the substance or the parts that contribute to the existing technology or a part of the technical schemes of the present disclosure may be embodied in the form of a software product, which is stored in a storage medium and includes a number of instructions to cause a computer device (which can be a personal computer, a server, or a network device, etc.) to execute all or some of the steps of the method in the embodiments of the present disclosure. The aforementioned storage medium includes: various media that can store program codes, such as a USB flash drive, a mobile hard disk, a read-only memory (ROM), a random access memory (RAM), a magnetic disk or an optical disk.

The logic and/or steps represented in the flowchart or described herein in other ways may be regarded as a sequential list of executable instructions for implementing logical functions, which can be specifically embodied in any computer-readable medium for use by instruction execution systems, apparatuses, or devices (such as a computer-based system, a system including a processor, or any other system that can fetch and execute instructions from an instruction execution system, apparatus, or device), or in conjunction with these instruction execution systems, apparatuses, or devices. For the purposes of this specification, “computer-readable medium” may be any device that can contain, store, communicate, propagate, or transmit programs for use by instruction execution systems, apparatuses, or devices, or apparatuses used in conjunction with these instruction execution systems, apparatuses, or devices.

More specific examples of computer-readable media (non-exhaustive list) include the following: an electrical connection having one or more wires (electronic devices), portable computer diskette (magnetic devices), random-access memory (RAM), read-only memory (ROM), erasable programmable read-only memory (EPROM or Flash memory), optical fiber devices, and portable compact disc read-only memory (CD-ROM). Additionally, a computer-readable medium may even be paper or other suitable media on which programs can be printed, as programs can be electronically obtained, for example, by optically scanning the paper or other media, followed by editing, interpreting, or processing in another suitable manner as necessary, and then storing them in a computer memory.

It should be understood that the various parts of the present disclosure may be implemented in hardware, software, firmware, or a combination thereof. In the above embodiments, a plurality of steps or methods may be implemented using software or firmware that is stored in memory and executed by a suitable instruction execution system. For example, if implemented with hardware, as in another embodiment, any one of the following techniques known in the art or their combinations may be used: discrete logic circuits with logic gate circuits for implementing logical functions on data signals, application specific integrated circuits with suitable combinational logic gate circuits, programmable gate arrays (PGA), field programmable gate arrays (FPGA), etc.

In the foregoing description, the explanation with reference to the terms “an implementation/embodiment”, “another implementation/embodiment” or “some implementations/embodiments”, etc. means that specific features, structures, materials or characteristics described in connection with the embodiment(s) or example(s) are included in at least one embodiment or example of the present disclosure. In the description, the illustrative expressions of the above-mentioned terms do not necessarily refer to the same embodiments or examples. Moreover, the specific features, structures, materials or characteristics described can be combined in any one or more embodiments or examples in any suitable manner.

Although the embodiments of the present disclosure have been shown and described, it can be understood by those of ordinary skill in the art that various changes, modifications, substitutions and variations may be made to these embodiments without departing from the principles and objectives of the present disclosure, and the scope of the present disclosure is defined by the claims and their equivalents.

The above is a detailed description of the preferred implementation of the present disclosure, but the present disclosure is not limited to the embodiments described above. Those of ordinary skill in the art can make various equivalent modifications or replacements without departing from the gist of the present disclosure, and these equivalent modifications or replacements are all included in the scope defined by the claims of the present disclosure.

1. A water demand forecasting method for scheduling water resources, comprising at least one processor, a memory operatively coupled to the at least one processor, and processor executable instructions for causing the at least one processor to perform the method: the water demand forecasting method is executed by the at least one processor and comprises:
acquiring first raw water consumption data corresponding to historical water demand data within a first water consumption region and second raw water consumption data corresponding to historical water demand data within a second water consumption region, wherein each of the first raw water consumption data and the second raw water consumption data includes maximum water consumption data and minimum water consumption data;
based on the maximum water consumption data and minimum water consumption data of the first raw water consumption data, normalizing the first raw water consumption data to obtain first historical water consumption data, and based on the maximum water consumption data and minimum water consumption data of the second raw water consumption data, normalizing the second raw water consumption data to obtain second historical water consumption data;
constructing a network structure model based on the first historical water consumption data and the second historical water consumption data, and acquiring a spatial water demand correlation strength output by the network structure model, wherein the spatial water demand correlation strength is used to characterize a degree of influence from water demand changes in the second water consumption region on the first water consumption region, and the first water consumption region neighbors the second water consumption region;
inputting the first historical water consumption data into a pretrained temporal memory model for calculating a water demand of the first water consumption region based on temporal dependencies in the first historical water consumption data, resulting in a first temporal water demand forecast result; and
applying spatial adjustment, based on the spatial water demand correlation strength and the second historical water consumption data, to the first temporal water demand forecast result to obtain a target water demand result,
scheduling the water resources within the first water consumption region based on the obtained target water demand result;
wherein the spatial water demand correlation strength is a weight parameter between a first node and a parent node, the first node is a node formed by the first historical water consumption data in the network structure model, and the parent node is a node formed by the second historical water consumption data in the network structure model; and
the weight parameter between the first node and the parent node is determined according to a regression model.

2. (canceled)

3. The water demand forecasting method of claim 1, wherein the network structure model is constructed by:
acquiring preset orientation rules;
constructing a complete graph of nodes based on the first historical water consumption data and the second historical water consumption data;
performing a pair-wise independence test/update on a pair of nodes in the complete graph of nodes to obtain an undirected graph of nodes; and
performing an orientation update on the undirected graph of nodes according to the orientation rules to obtain the network structure model.

4. The water demand forecasting method of claim 3, wherein performing a pair-wise independence test/update on a pair of nodes in the complete graph of nodes comprises:
acquiring a preset significance indicator and a pair of nodes in the complete graph of nodes, as well as a set of nodes corresponding to the pair of nodes;
performing a test of independence on the pair of nodes based on the set of nodes to obtain an independence statistic;
comparing the independence statistic with the significance indicator to obtain a comparison result; and
removing an undirected edge corresponding to the pair of nodes in response to the comparison result indicating that the independence statistic is greater than the significance indicator; or, retaining an undirected edge corresponding to the pair of nodes in response to the comparison result indicating that the independence statistic is less than or equal to the significance indicator.

5. The water demand forecasting method of claim 4, wherein performing a test of independence on the pair of nodes based on the set of nodes to obtain an independence statistic comprises:
acquiring a third node and a second node from the pair of nodes;
performing a first conditional probability test on the third node based on the set of nodes to obtain a first node probability, and performing a second conditional probability test on the third node based on the set of nodes and the second node to obtain a second node probability; and
performing a statistical test on the second node probability based on the first node probability to obtain the independence statistic.

6. (canceled)

7. The water demand forecasting method of claim 1, wherein applying spatial adjustment, based on the spatial water demand correlation strength and the second historical water consumption data, to the first temporal water demand forecast result to obtain a target water demand result comprises:
acquiring, based on the temporal memory model, a second temporal water demand forecast result corresponding to the second water consumption region;
performing intra-region spatial adjustment on the second temporal water demand forecast result based on the spatial water demand correlation strength and the second historical water consumption data to obtain intra-region correction data; and
performing neighboring-region spatial adjustment on the first temporal water demand forecast result based on the intra-region correction data to obtain the target water demand result.

8. A water demand forecasting system for scheduling water resources, comprising at least one processor, wherein the at least one processor is configured to execute instruction to cause the system to perform operations comprising:
acquire first raw water consumption data corresponding to a first water consumption region and second raw water consumption data corresponding to a second water consumption region;
preprocess the first raw water consumption data to obtain first historical water consumption data, and preprocess the second raw water consumption data to obtain second historical water consumption data;
construct a network structure model based on the first historical water consumption data and the second historical water consumption data, and acquire a spatial water demand correlation strength output by the network structure model, wherein the spatial water demand correlation strength is used to characterize a degree of influence from water demand changes in the second water consumption region on the first water consumption region, and the first water consumption region neighbors the second water consumption region;
input the first historical water consumption data into a temporal memory model for forecasting a water demand of the first water consumption region based on temporal dependencies in the first historical water consumption data, resulting in a first temporal water demand forecast result; and
apply spatial adjustment, based on the spatial water demand correlation strength and the second historical water consumption data, to the first temporal water demand forecast result to obtain a target water demand result,
wherein the spatial water demand correlation strength is a weight parameter between a third node and a parent node, the third node is a node formed by the first historical water consumption data in the network structure model, and the parent node is a node formed by the second historical water consumption data in the network structure model; and
schedule the water resources within the first water consumption region based on the obtained target water demand result;
wherein the weight parameter between the third node and the parent node is determined according to a regression model.

9. An electronic device, comprising:
at least one processor; and
at least one memory for storing at least one program, wherein:
the at least one program, when executed by the at least one processor, causes the at least one processor to implement the method of claim 1.

10. A non-transitory computer-readable storage medium in which a processor-executable program is stored, wherein the processor-executable program, when executed by a processor, causes the processor to implement the method of claim 1.
